(19) United States
(12) Patent Application Publication
(10) Pub. No.: US 2026/0333705 A1
(43) Pub. Date: Oct. 22, 2026

(54) FERROELECTRIC MEMORY DEVICE WITH SEMICONDUCTOR LAYER

(71) Applicant: Taiwan Semiconductor Manufacturing Company, Ltd., Hsinchu (TW)

(72) Inventors: Yi-Hsuan Chen, Taoyuan City (TW); Kuo-Ching Huang, Hsinchu City (TW); Yi Ching Ong, Hsinchu (TW); Kuen-Yi Chen, Hsinchu City (TW)

(21) Appl. No.: 19/723,095

(22) Filed: Jun. 29, 2026

Related U.S. Application Data
(62) Division of application No. 18/321,239, filed on May 22, 2023.

(51) Int. Cl. H10B 51/30; H10B 51/10; H10D 30/01; H10D 30/69; H10D 64/68; H10W 20/41; H10W 20/42

(52) U.S. Cl. CPC H10B 51/30; H10B 51/10; H10D 30/0415; H10D 30/701; H10D 64/689; H10W 20/42; H10W 20/435

(57) ABSTRACT

In some embodiments, the present disclosure provides an integrated chip including a first electrode made of a metal; a second electrode disposed over the first electrode; a ferroelectric layer between the first and second electrodes; and an interfacial layer separating the ferroelectric layer and the first electrode, the interfacial layer comprising a semiconductor material and configured to space the first electrode from the ferroelectric layer.

### REFERENCE TO RELATED APPLICATION

This Application is a Divisional of U.S. application Ser. No. 18/321,239, filed on May 22, 2023, the contents of which are hereby incorporated by reference in their entirety.

### BACKGROUND

Many modern-day electronic devices include non-volatile memory. Non-volatile memory is electronic memory that is able to store data in the absence of power. Promising candidates for the next generation of non-volatile memory include ferroelectric random-access memory (FeRAM). FeRAM has a relatively simple structure and is compatible with complementary metal-oxide-semiconductor (CMOS) logic fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a memory cell comprising an interfacial layer that is a semiconductor.

FIGS. 2A and 2B illustrate cross-sectional views of some alternative embodiments of the memory cell of FIG. 1.

FIGS. 3A and 3B illustrate various I/V charts of some embodiments of the memory cells of FIGS. 1 and 2A.

FIG. 4 illustrates a cross sectional view of some embodiments of the memory cell of FIG. 1 in which the memory cell is integrated with an interconnect structure of an integrated circuit (IC) chip.

FIG. 5 illustrates a cross sectional view of some alternative embodiments of the memory cell of FIG. 4 in which a top-electrode width is reduced relative to a remainder of the memory cell.

FIG. 6 illustrates a cross sectional view of some alternative embodiments of the memory cell of FIG. 1 in which constituents of the memory cell have U-shaped profiles.

FIG. 7 illustrates a cross sectional view of some alternative embodiments of the memory cell of FIG. 6.

FIG. 8A-8B illustrate cross sectional views of some alternative embodiments of the memory cell of FIG. 1 in which a top electrode surrounds a bottom electrode.

FIGS. 9A-9E illustrate cross-sectional views of some alternative embodiments of the memory cell of FIG. 2A in which the interfacial layer is at a bottom electrode.

FIGS. 10A and 10B illustrate cross-sectional views of some embodiments of an IC chip comprising memory cells integrated into individual one-transistor one-resistor (1T1R) cells and configured as in FIGS. 4-8.

FIG. 11 illustrates a cross-sectional view of some alternative embodiments of the IC chip of FIGS. 10A and 10B.

FIG. 12 illustrates a top layout view of some embodiments of the IC chip of FIGS. 10A and 10B.

FIGS. 13-23 illustrate a series of cross-sectional views of some embodiments of a method for forming an IC chip comprising memory cells which are integrated into individual 1T1R cells and which comprise interfacial layers consisting of semiconductor material.

FIG. 24 illustrates a flow diagram of some embodiments of the method of FIGS. 13-23.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit (IC) chip may comprise an interconnect structure and a memory cell in the interconnect structure. The memory cell comprises a bottom electrode, a ferroelectric layer overlying the bottom electrode, a top electrode overlying the ferroelectric layer, and an interfacial layer directly contacting the ferroelectric layer between the ferroelectric layer and one of the top or bottom electrodes. The interconnect structure comprises a bottom electrode wire underlying the memory cell and a top electrode wire overlying the memory cell. Further, the interconnect structure comprises vias extending respectively from the bottom and top electrode wires respectively to the bottom and top electrodes. The interfacial layer is an insulator that increases a tunneling resistance ratio of the memory cell. That is, the interfacial layer causes the memory cell to have a higher change in resistance between a first and second polarizations of the ferroelectric layer.

A challenge with the memory cell is that the interfacial layer has a minimum thickness and a high band gap. Such a high band gap may, for example, be greater than about 3 electron volts or some other suitable value. Materials with a high bandgap reduce the current flow through the memory cell. As such, the combination of the ferroelectric and the interfacial layer may have a low tunneling current density during read operations due to the combined thickness of the layers and the high band gap. Lowering the thickness of the ferroelectric layer and the interfacial layer may inhibit the bulk properties (e.g., a dielectric constant) of the layers, which may be undesirable. A low tunneling current density during read operations negatively impacts performance of the memory cell. For example, a low tunneling current density during read operations may cause increased sensing times.

Various embodiments of the present disclosure are directed towards a memory cell comprising an interfacial layer consisting of a semiconductor material. More particularly, a semiconductor material with a band gap of less than 3 electron volts (eV) is directly between the ferroelectric layer and one of the top or bottom electrodes.

Because the interfacial layer consists of the semiconductor material with a lower bandgap than that of an insulative material, the tunneling current density of the memory cell may be increased relative to memory cells with an interfacial layer consisting of the insulative material. By increasing the tunneling current density of the ferroelectric layer and interfacial layer, performance of the ferroelectric layer and hence of the memory cell may be enhanced. For example, sensing times during read operations may be decreased. Further, the memory cell is compatible with pre-existing manufacturing processes, whereby the memory device cell may be used for embedded memory applications.

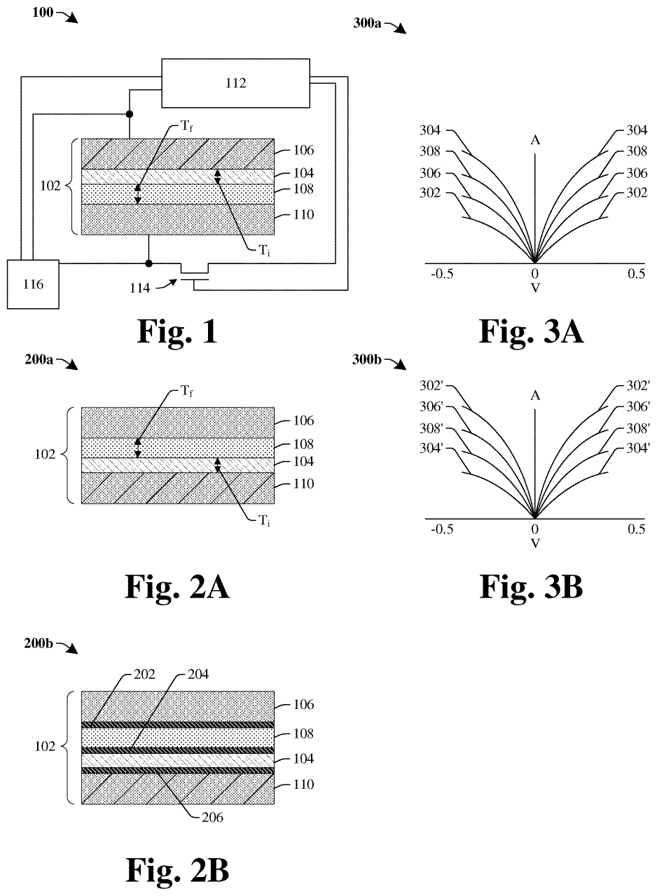

With reference to FIG. 1, a cross-sectional view 100 of some embodiments of a memory cell 102 is provided in which an interfacial layer 104 is configured to space a top electrode 106 from a ferroelectric layer 108. In some embodiments, the interfacial layer 104 may additionally or alternatively be referred to as a blocking layer, an intermixing layer, a diffusion barrier layer, the like, or any combination of the foregoing. The memory cell 102 may, for example, be or comprise a metal-ferroelectric-semiconductor-metal (MFSM) cell, a ferroelectric tunnel junction (FTJ), the like, or any combination of the foregoing.

The ferroelectric layer 108 overlies a bottom electrode 110, the interfacial layer 104 overlies the ferroelectric layer 108, and the top electrode 106 overlies the interfacial layer 104. Further, the interfacial layer 104 consists of a semiconductor material. For example, in some embodiments, the interfacial layer 104 is or comprises one of crystalline or amorphous elemental silicon (Si), germanium (Ge), gallium arsenide (GaAs), silicon carbide (SiC), tin selenide (SnSe), cadmium telluride (CdTe), indium phosphide (InP), boron arsenide (BAs), the like, or a combination of the foregoing.

In some embodiments, the interfacial layer 104 consists of a material which has a band gap of less than 3 eV. For example, the interfacial layer 104, in some embodiments, consists of germanium, which has a band gap of 0.8 eV. An interfacial layer 104 with a high band gap (e.g., above 3 eV) negatively impacts the performance of the memory cell 102. The interfacial layer 104 has a thickness Tᵢ between the ferroelectric layer 108 and the top electrode 106, reducing the current density of the memory cell 102 while providing other benefits (e.g., increasing the difference in resistance of the memory cell between two ferroelectric states). If the interfacial layer 104 has a high band gap, current density through the memory cell 102 may be reduced further. A reduction in the current density will increase the sensing time of the memory cell 102 and slow operation of the integrated chip to undesirable levels. Therefore, forming the interfacial layer 104 using a material with a low band gap (e.g., a semiconductor material with a band gap of less than 3 eV) may increase the current density of the memory cell 102, thereby decreasing the sensing time of read operations. In some embodiments, the memory cell 102 is configured to function as a ferroelectric tunnel junction, and the ferroelectric tunnel junction is configured to support a tunneling current density of 100 A/cm₂. In some embodiments, bias circuitry 112 is configured to supply a bias voltage to the ferroelectric tunnel junction, resulting in a tunneling current density greater than or equal to 100 A/cm². In some embodiments, there is no dielectric material directly between the top electrode 106 and the bottom electrode 110. In other embodiments, there may be dielectric material directly between the top electrode 106 and the bottom electrode 110, due to a native oxide layer forming in the semiconductor layer, or some other process. However, the dielectric layer results in decreased current density and increased sensing time, and does not exceed 20 angstroms in thickness.

In some embodiments, the interfacial layer 104 has the thickness Tᵢ of about 50-1200 angstroms, about 50-600 angstroms, about 600-1200 angstroms, or some other suitable value. If the thickness Tᵢ is too small (e.g., less than 50 angstroms), bulk properties of the interfacial layer 104 such as the dielectric constant may be reduced or altered undesirably. If the thickness Tᵢ is too large (e.g., more than 1200 angstroms), a resistance of the interfacial layer 104 may be too high and may lead to low current density through the memory cell 102.

In some embodiments, a thickness T_{f} of the ferroelectric layer 108 is about 50-400 angstroms, about 50-200 angstroms, about 200-400 angstroms, or some other suitable value. If the thickness T_{f} is too small (e.g., less than 50 angstroms) or is too large (e.g., greater than 400 angstroms), the ferroelectric layer 108 may have no remanent polarization or may have an unusably small remanent polarization. Further, if the thickness T_{f} is too large (e.g., greater than 400 angstroms), a resistance of the ferroelectric layer 108 may be too high and may lead to low current flow through the memory cell 102. In some embodiments, the ratio of thicknesses between the thickness Tᵢ of the interfacial layer 104 and the thickness T_{f} of the ferroelectric layer 108 is from a 1 to 1 ratio to a 3 to 1 ratio.

During operation of the memory cell 102, the remanent polarization of the ferroelectric layer 108 is used to represent a bit of data. For example, a positive polarity of the remanent polarization may represent a binary “0”, whereas a negative polarity of the remanent polarization may represent a binary “1”, or vice versa.

To set the remanent polarization to the positive polarity, a first write voltage is applied by the bias circuitry 112 across the ferroelectric layer 108 from the top electrode 106 to the bottom electrode 110. To set the remanent polarization to the negative polarity, a second write voltage is applied across the ferroelectric layer 108 from the top electrode 106 to the bottom electrode 110. The first and second write voltages have opposite polarities and have magnitudes in excess of a coercive voltage (e.g., a voltage threshold beyond which the remanent polarization of the ferroelectric layer is changed). In some embodiments, to read the polarity of the remanent polarization, a read voltage less than the coercive voltage is applied by the bias circuitry 112 across the ferroelectric layer 108. A current passing through the memory cell 102 is then read, which will vary based on the remanent polarization of the ferroelectric layer 108. For example, in the configuration shown in FIG. 1, the read voltage will elicit a higher current when the remanent polarization is set to the negative polarity. In some embodiments, there may be a difference of several orders of magnitude between the current passing through the memory cell 102 in the positive polarity and the negative polarity. Hence, the current may be used to identify the polarity of the remanent polarization.

In some embodiments, an access transistor 114 is used to control which memory cell 102 of the IC chip is being read. The access transistor 114 is controlled by the bias circuitry 112. In some embodiments, control circuitry 116 is configured to control the bias circuitry 112 and read the current passing through the ferroelectric tunnel junction.

FIG. 2A shows a cross-sectional view 200a of an alternative embodiment of the memory cell of FIG. 1, where the interfacial layer 104 is directly between the ferroelectric layer and the bottom electrode 110. During read operations, using a same read voltage as in the example given above, the change in order of the interfacial layer 104 and the ferroelectric layer 108 will result in a higher current being conducted when the remanent polarization is set to the positive polarity.

In some embodiments, the ferroelectric layer 108 is or comprises a binary oxide, a ternary oxide or nitride, a quaternary oxide, some other suitable ferroelectric material(s), or any combination of the foregoing. The binary oxide may, for example, be or comprise hafnium oxide (e.g., hafnia or HfO₂) and/or some other suitable binary oxide(s). The ternary oxide or nitride may, for example, be or comprise hafnium silicate (e.g., HfSiOₓ), hafnium zirconate (e.g., HfZrOₓ), barium titanate (e.g., BaTiO₃), lead titanate (e.g., PbTiO₃), strontium titanate (e.g., SrTiO₃), calcium manganite (e.g., CaMnO₃), bismuth ferrite (e.g., BiFeO₃), aluminum scandium nitride (e.g., AlScN), aluminum gallium nitride (e.g., AlGaN), aluminum yttrium nitride (e.g., AlYN), some other suitable ternary oxide(s) and/or nitride(s), or any combination of the foregoing. The quaternary oxide may, for example, be or comprise barium strontium titanate (e.g., BaSrTiOₓ) and/or some other suitable quaternary oxide(s).

In some embodiments, the top and bottom electrodes 106, 110 are or comprise one of copper (Cu), platinum (Pt), aluminum copper (AlCu), gold (Au), silver (Ag), titanium (Ti), tantalum (Ta), tungsten (W), another conductive material, the like, or any combination of the foregoing. In some embodiments, the top electrode 106 comprises a same material as the bottom electrode 110. In other embodiments, the top electrode 106 comprises one or more different materials than the bottom electrode 110. In some embodiments, the bottom electrode 110 is a first electrode and the top electrode 106 is a second electrode. In some embodiments, the top and bottom electrodes 106, 110 consist of titanium, the ferroelectric layer 108 consists of hafnium oxide, and the interfacial layer 104 consists of elemental silicon.

FIG. 2B shows a cross-sectional view 200b of an alternative embodiment of the memory cell of FIG. 2A where first, second, and third intermediate layers 202, 204, 206 are separating the layers of the memory cell. In some embodiments, the first, second, and third intermediate layers 202, 204, 206 are sandwiched between different layers of the memory cell 102. In further embodiments, the first, second, and third intermediate layers 202, 204, 206 are or comprise a first material that is the same as that of the layer contacting a respective top surface, and a second material that is the same as that of the layer contacting a respective bottom surface of the intermediate layers. For example, in some embodiments, the first intermediate layer 202 is or comprises a same material as the top electrode 106 (the first material) and a same material as the ferroelectric layer 108 (the second material). In further embodiments, the first material is distributed through the first intermediate layer 202 in a gradient from a first surface contacting the top electrode 106 to a second surface contacting the ferroelectric layer 108. For example, in an embodiment where the top electrode is made of titanium (Ti) and the ferroelectric layer is made of hafnium oxide (HfO₂), the first intermediate layer may comprise approximately 99% Ti and 1% HfO₂ by mole percent at the first surface. Further, the first intermediate layer may comprise approximately 1% Ti and 99% HfO₂ by mole percent at the second surface. In further embodiments, the ratio of HzO₂ to Ti may increase monotonically from the first surface to the second surface, and the ratio of Ti to HfO₂ may decrease monotonically from the second surface to the first surface. For example, “monotonically” can be linearly, exponentially, quadratically, or according to a Gaussian function, among others. In some embodiments, the second and third intermediate layers 204, 206 may have a similar gradient of materials between the materials of the ferroelectric layer 108, the interfacial layer 104, and the bottom electrode 110. In some embodiments, the first, second, and third intermediate layers 202, 204, 206 have thicknesses of less than 1 nanometer. In further embodiments, the thicknesses of the first, second, and third intermediate layers 202, 204, 206 are measured from where the mole percent of the first material is approximately 99% to where the mole percent of the second material is approximately 99%. In some embodiments, the first, second, and third intermediate layers 202, 204, 206 are formed during an annealing process performed on the memory cell 102 to increase the amount of the ferroelectric layer 108 that is in the orthorhombic phase.

FIGS. 3A and 3B illustrate various I/V charts 300a, 300b of some embodiments of the memory cells of FIGS. 1 and 2A. FIG. 3A shows the read currents of some embodiments shown in FIG. 1 with varying dielectric constants and remanent polarizations. Lines 302, 304 represent a memory cell where the semiconductor material has a lower dielectric constant, while lines 306, 308 represent a memory cell where the semiconductor material has a higher dielectric constant. The lines 302 and the line 306 each represent the current flow through the memory cell 102 at various voltages when the ferroelectric layer 108 (see FIG. 1) has a positive polarity. The line 304 and the line 308 each represent the current flow through the memory cell 102 at various voltages when the ferroelectric layer 108 (see FIG. 1) has a negative polarity.

FIG. 3B shows the read currents of some embodiments shown in FIG. 2A with varying dielectric constants and remanent polarizations. The lines 302′, 304′ represent a memory cell where the semiconductor material has a lower dielectric constant, while lines 306′, 308′ represent a memory cell where the semiconductor material has a higher dielectric constant. The lines 302′ and the line 306′ each represent the current flow through the memory cell 102 at various voltages when the ferroelectric layer 108 (see FIG. 2A) has the negative polarity. The line 304′ and the line 308′ each represent the current flow through the memory cell 102 at various voltages when the ferroelectric layer 108 (see FIG. 2A) has a positive polarity.

The dielectric constant of the interfacial layer 104 affects the difference in resistance values between the positive and negative polarity. The dielectric constant of the interfacial layer 104 is dependent on the material used to form the interfacial layer 104 as well as the crystalline properties of the material. For example, in some cases, the interfacial layer 104 can be an amorphous interfacial layer (e.g., amorphous silicon), and in other cases, the interfacial layer 104 can be a crystalline interfacial layer (e.g., crystalline silicon), which has a lower dielectric constant than the amorphous interfacial layer.

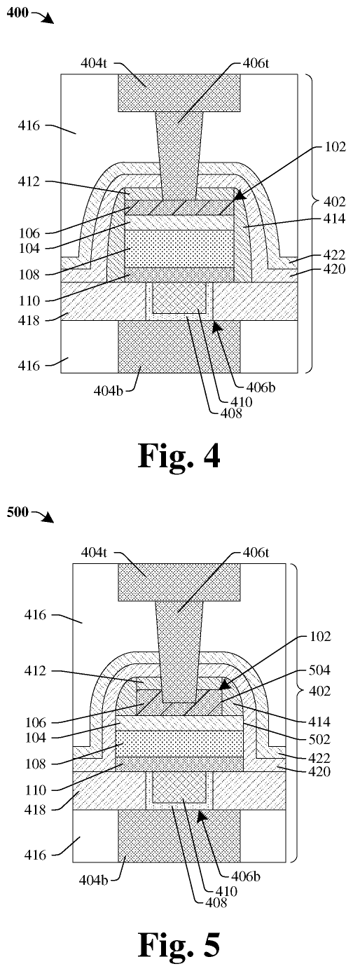

With reference to FIG. 4, a cross-sectional view 400 of some embodiments of the memory cell 102 of FIG. 1 is provided in which the memory cell 102 is integrated into an interconnect structure 402 of an IC chip.

A top electrode wire 404t overlies the memory cell 102, and a top electrode via (TEVA) 406t extends downward from the top electrode wire 404t to the top electrode 106. A bottom electrode wire 404b underlies the memory cell 102, and a bottom electrode via (BEVA) 406b extends upward from the bottom electrode wire 404b to the bottom electrode 110. The BEVA 406b comprises a BEVA barrier 408 and a BEVA body 410. The BEVA barrier 408 cups an underside of the BEVA body 410 to separate the BEVA body 410 from the bottom electrode wire 404b. In alternative embodiments, the BEVA barrier 408 is omitted, such that the BEVA body 410 directly contacts the bottom electrode wire 404b. The BEVA barrier 408 may, for example, be configured to block or otherwise substantially decrease diffusion of material from the bottom electrode wire 404b to the bottom electrode 110.

In some embodiments, the top electrode wire 404t, the TEVA 406t, and the bottom electrode wire 404b are or comprise copper, aluminum, tungsten, the like, or any combination of the foregoing. In some embodiments, the BEVA body 410 is or comprises: (1) a same material as the top electrode wire 404t, the TEVA 406t, the bottom electrode wire 404b, or any combination of the foregoing; (2) a same material as the BEVA barrier 408; (3) a same material as the bottom electrode 110; (4) some other suitable material(s); or (5) any combination of the foregoing. In some embodiments, the BEVA barrier 408 is or comprises titanium nitride, platinum, aluminum copper, gold, titanium, tantalum, tantalum nitride, tungsten, tungsten nitride, the like, or any combination of the foregoing. In some embodiments, a thickness of the BEVA barrier 408 is about 50-200 angstroms or some other suitable value.

A hard mask 412 overlies the top electrode 106, and the TEVA 406t extends through the hard mask 412 from the top electrode wire 404t to the top electrode 106. In alternative embodiments, the hard mask 412 is omitted. The hard mask 412 may, for example, be or comprise titanium nitride, silicon oxide, silicon nitride, silicon carbide nitride, silicon oxide nitride, metal oxide, some other suitable material(s), or any combination of the foregoing. The metal oxide may, for example, be or comprise titanium oxide, aluminum oxide, some other suitable metal oxide(s), or any combination of the foregoing. In some embodiments, a thickness of the hard mask 412 is about 50-400 angstroms or some other suitable value.

As described with regard to FIG. 1, the interfacial layer 104 is configured to space the top electrode 106 from the ferroelectric layer 108. This may, in turn, enhance performance of the ferroelectric layer 108.

The bottom electrode 110, the ferroelectric layer 108, the interfacial layer 104, the top electrode 106, and the hard mask 412 share a common width and form a pair of common sidewalls respectively on opposite sides of the memory cell 102. That is, the ferroelectric layer has a first outer sidewall, the interfacial layer has a second outer sidewall, and the bottom and top electrodes have a third and fourth outer sidewall aligned with the first outer sidewall and the second outer sidewall. Further, the common sidewalls have planar profiles but may alternatively have curved profiles or other suitable profiles.

A sidewall spacer structure 414 is on the common sidewalls. The sidewall spacer structure 414 may, for example, be or comprise titanium nitride, silicon oxide, silicon nitride, silicon carbide nitride, silicon oxide nitride, metal oxide, some other suitable material(s), or any combination of the foregoing. The metal oxide may, for example, be or comprise titanium oxide, aluminum oxide, some other suitable metal oxide(s), or any combination of the foregoing. In some embodiments, the sidewall spacer structure 414 is a same material as the hard mask 412.

A plurality of intermetal dielectric (IMD) layers 416 respectively surround the bottom electrode wire 404b and the top electrode wire 404t. Further, a first etch stop layer 418, a second etch stop layer 420, and a buffer layer 422 separate the IMD layers 416. The first etch stop layer 418 surrounds the BEVA 406b, vertically between the bottom electrode wire 404b and the memory cell 102. The second etch stop layer 420 and the buffer layer 422 cover and conform to the first etch stop layer 418 and the memory cell 102. Further, the second etch stop layer 420 is between the buffer layer 422 and the memory cell 102.

The IMD layers 416 may, for example, be or comprise silicon oxide, silicon nitride, silicon carbide, silicon oxycarbide, silicon oxynitride, silicon carbonitride, some other suitable dielectric(s), or any combination of the foregoing. The first etch stop layer 418 and/or the second etch stop layer 420 may, for example, be or comprise metal nitride, metal oxide, metal carbide, silicon nitride, silicon oxide, silicon carbide, silicon oxynitride, some other suitable dielectric(s), or any combination of the foregoing. In some embodiments, the first etch stop layer 418 and the second etch stop layer 420 are a same material. In some embodiments, a thickness of the first etch stop layer 418 is about 150-350 angstroms or some other suitable value. In some embodiments, a thickness of the second etch stop layer 420 is about 50-300 angstroms or some other suitable value. The buffer layer 422 may, for example, be or comprise tetraethyl orthosilicate (TEOS) oxide and/or some other suitable dielectric(s). In some embodiments, a thickness of the buffer layer 422 is about 50-300 angstroms or some other suitable value.

With reference to FIG. 5, a cross-sectional view 500 of some alternative embodiments of the memory cell 102 of FIG. 4 is provided in which a top-electrode width is reduced relative to a remainder of the memory cell 102.

The bottom electrode 110, the ferroelectric layer 108, and the interfacial layer 104 share a first common width and form a pair of first common sidewalls 502 respectively on opposite sides of the memory cell 102. That is, an outermost sidewall of the interfacial layer 104 is aligned with an outermost sidewall of the bottom electrode 110 and the bottommost sidewall of the ferroelectric layer 108. Further, the top electrode 106 and the hard mask 412 share a second common width and form a pair of second common sidewalls 504 respectively on the opposite sides of the memory cell 102. That is, an outermost sidewall of the top electrode 106 is aligned with an outermost sidewall of the hard mask 412. The second common width is less than the first common width, and the second common sidewalls 504 are laterally between the first common sidewalls 502. Further, the second common sidewalls 504 are covered by the sidewall spacer structure 414, which overlies the interfacial layer 104. The first and second common sidewalls have planar profiles, but other suitable profiles are amenable.

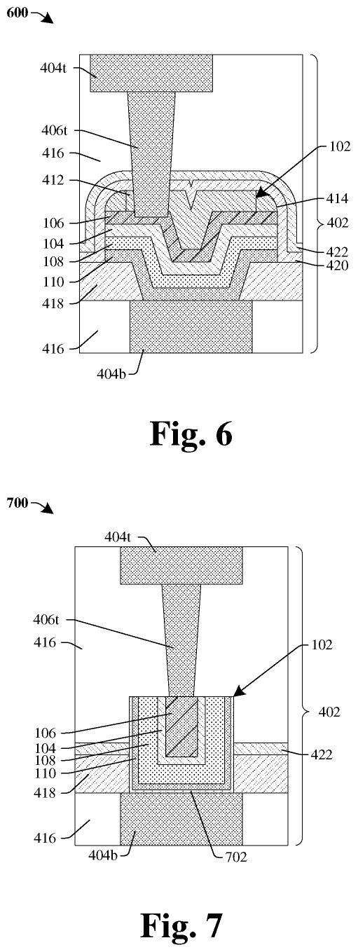

With reference to FIG. 6, a cross-sectional view 600 of some alternative embodiments of the memory cell 102 of FIG. 5 is provided in which the BEVA barrier 408 and the BEVA body 410 are omitted. Instead, the bottom electrode 110 directly contacts the bottom electrode wire 404b. The bottom electrode 110, the ferroelectric layer 108, the interfacial layer 104, the top electrode 106, and the hard mask 412 are depressed at the bottom electrode wire 404b, and the TEVA 406t is laterally offset from a center of the memory cell 102. In some embodiments, a bottom surface of the top electrode 106 extends beneath a top surface of the bottom electrode 110.

With reference to FIG. 7, a cross-sectional view 700 of some alternative embodiments of the memory cell 102 of FIG. 4 is provided in which the BEVA 406b, (including the BEVA barrier 408 and the BEVA body 410), the sidewall spacer structure 414, the second etch stop layer 420, and the hard mask 412 are omitted. As such, the memory cell 102 extends from the bottom electrode wire 404b. Further, a bottom electrode barrier 702, the bottom electrode 110, the ferroelectric layer 108, and the interfacial layer 104 cup an underside of the top electrode 106. For example, the bottom electrode barrier 702, the bottom electrode 110, the ferroelectric layer 108, the interfacial layer 104 may each have U-shaped profiles or the like. The bottom electrode barrier 702 is between the bottom electrode 110 and the bottom electrode wire 404b and may, for example, be as the BEVA barrier 408 is described with regard to FIG. 4. In some embodiments, the top electrode 106, the interfacial layer 104, and the ferroelectric layer 108 are between inner sidewalls of the bottom electrode 110. In some embodiments, the top electrode 106 is directly between outer sidewalls and directly above upper surfaces of the ferroelectric layer 108, the interfacial layer 104, and the bottom electrode 110.

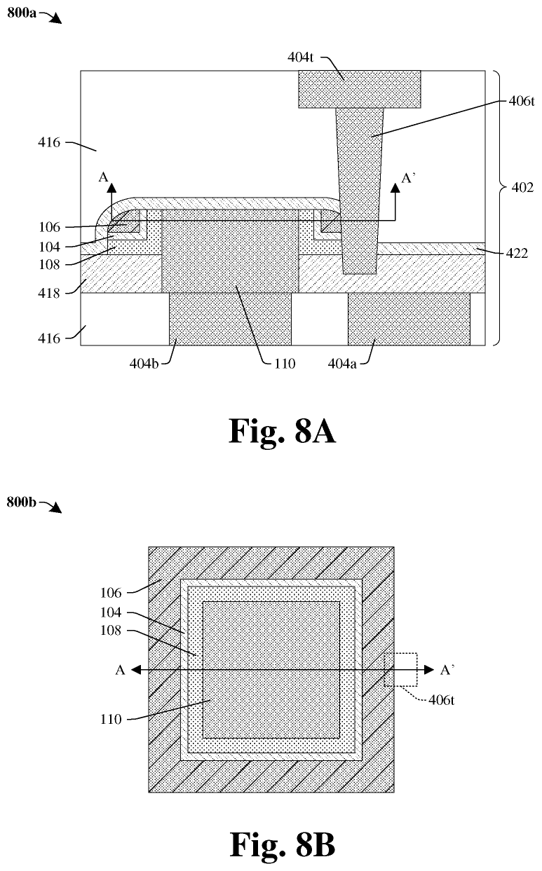

With reference to FIG. 8A, a cross-sectional view 800a of some alternative embodiments of the memory cell 102 of FIG. 4 is provided in which the BEVA 406b, (including the BEVA barrier 408 and the BEVA body 410), the sidewall spacer structure 414, the second etch stop layer 420, and the hard mask 412 are omitted. As such, the memory cell 102 extends from the bottom electrode wire 404b. Further, an additional wire 404a underlies the TEVA 406t, level with the bottom electrode wire 404b, and the top electrode 106, the interfacial layer 104, and the ferroelectric layer 108 form a sidewall spacer structure.

The sidewall spacer structure overlies the first etch stop layer 418 on portions of an outer sidewall of the bottom electrode 110. Further, the sidewall spacer structure has a pair of spacer segments between which the bottom electrode 110 is arranged. The TEVA 406t extends to a portion of the top electrode 106 at one of these segments and further extends into the first etch stop layer 418. In at least some embodiments, the spacer segments are continuous with each other outside the cross-sectional view 800a. The interfacial layer 104 and the ferroelectric layer 108 have L-shaped portions at each of the spacer segments. The L-shaped portions of the ferroelectric layer 108 wrap around bottom corners of corresponding L-shaped portions of the interfacial layer 104, and the L-shaped portions of the interfacial layer 104 wrap around bottom corners of corresponding portions of the top electrode 106. In some embodiments, the top electrode 106 extends in a closed path around the bottom electrode 110, and wherein the bottom electrode 110 has outer sidewalls that extend to an elevation level with an uppermost point of the top electrode 106.

With reference to FIG. 8B, a top layout view 800b of some embodiments of the memory cell 102 of FIG. 8A is provided. Further, a top layout of the TEVA 406t is illustrated in phantom overlaid on the memory cell 102. The cross-sectional view 800a of FIG. 8A may, for example, be taken along line A-A′. The top electrode 106 extends in a closed path around the interfacial layer 104, the interfacial layer 104 extends in a closed path around the ferroelectric layer 108, and the ferroelectric layer 108 extends in a closed path around the bottom electrode 110. The memory cell 102 has a square or rectangular top layout, but may alternatively have a circular top layout or some other suitable top layout. The TEVA 406t has a square or rectangular top layout but may alternatively have other suitable top layouts.

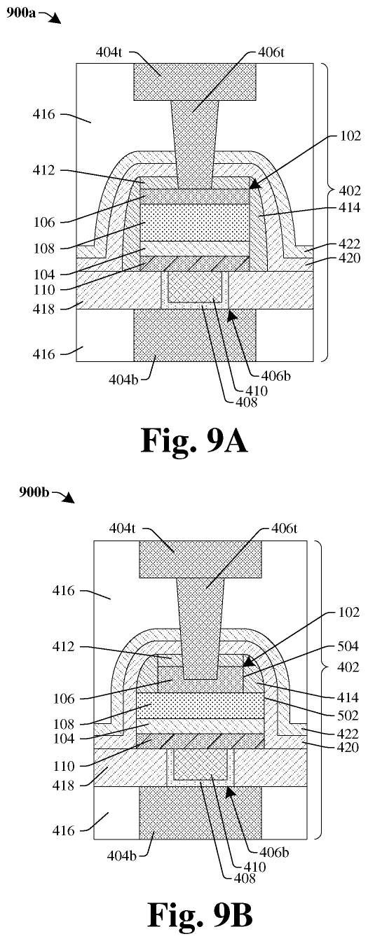

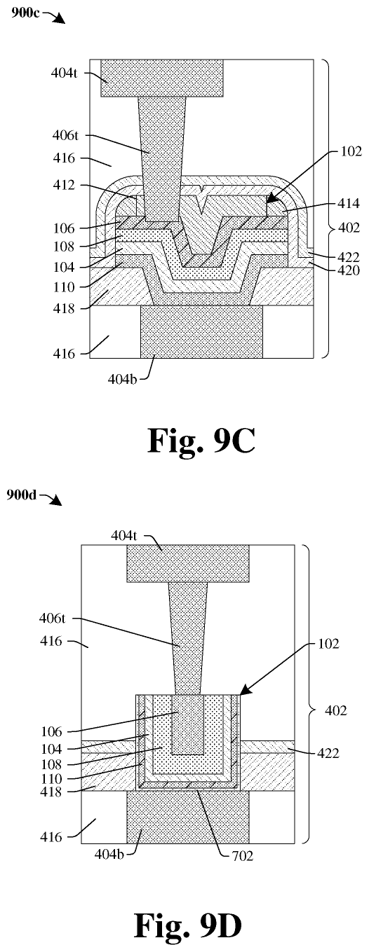

With reference to FIGS. 9A-9E, some cross-sectional views 900a-900e of some alternative embodiments of the memory cell 102 of FIG. 2A is provided in which the interfacial layer 104 is at the bottom electrode 110 as in FIG. 2A. In the cross-sectional views 900a-900e, some alternative embodiments of the memory cell 102 of FIG. 2A are provided in which the memory cell 102 is configured respectively as in FIGS. 4, 5, 6, 7, and 8A.

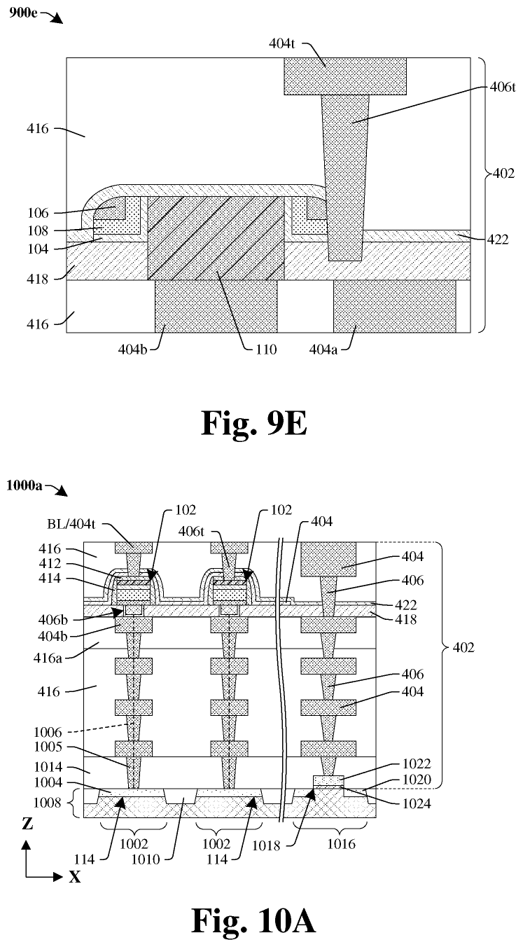

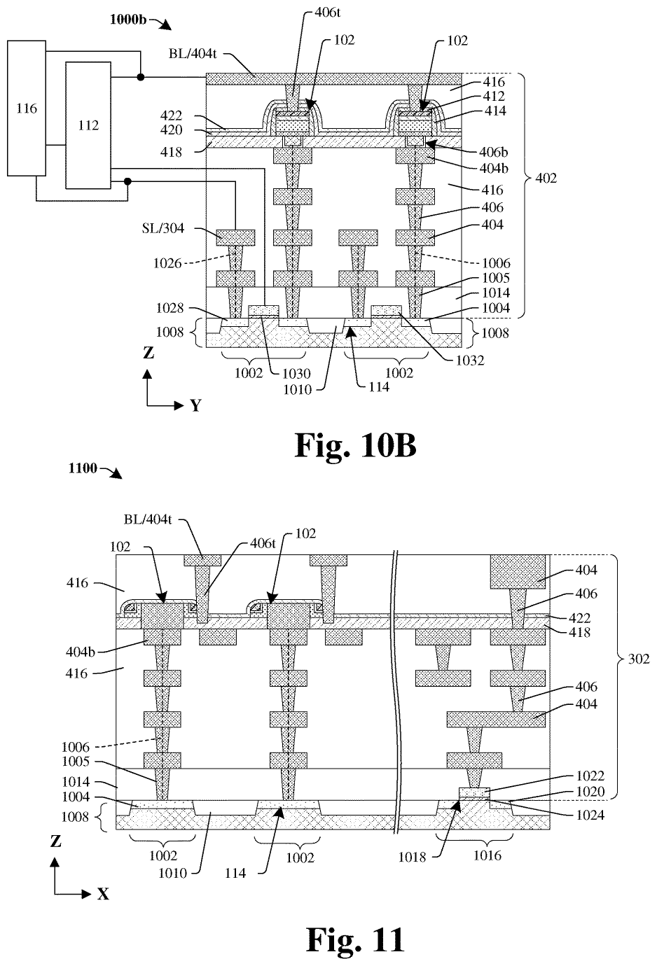

With reference to FIG. 10A, a cross-sectional view 1000a of some embodiments of an IC chip comprising memory cells 102 is provided, where the memory cells 102 are integrated into individual 1T1R cells 1002. The memory cells 102 are each as their counterpart is described with regard to FIG. 1.

The 1T1R cells 1002 comprise individual drain regions 1004 and individual drain-side conductive paths 1006. The drain regions 1004 are doped regions of a substrate 1008 and each has an opposite doping type as an adjoining region of the substrate 1008. Further, the drain regions 1004 are electrically separated by a trench isolation structure 1010 and partially define access transistors 114 (partially shown) used to individually select the memory cells 102. The trench isolation structure 1010 extends into a top of the substrate 1008 and comprises silicon oxide and/or some other suitable dielectric material(s). The substrate 1008 may, for example, be a bulk silicon substrate or some other suitable semiconductor substrate.

The drain-side conductive paths 1006 electrically couple the drain regions 1004 to the memory cells 102 and are formed by an interconnect structure 402 within which the memory cells 102 are arranged. The interconnect structure 402 comprises a plurality of wires 404 and a plurality of vias 406 alternatingly stacked into wire levels and via levels. The plurality of wires 404 comprises top electrode wires 404t and bottom electrode wires 404b. In some embodiments, the top electrode wires 404t correspond to bit lines BL. The plurality of vias 406 comprises TEVAs 406t and BEVAs 406b. A level of contacts 1005 extend between the plurality of wires 404 and the substrate 1008 in an interlayer dielectric (ILD) layer 1014, whereas levels of the vias 406 and the wires 404 are in IMD layers 416 above the ILD layer 1014. The wires 404 and the vias 406, except the BEVAs 406b, may be or comprise, for example, copper, aluminum, some other suitable metal(s), or any combination of the foregoing. The BEVAs 406b may, for example, be as their counterpart is described with regard to FIGS. 3A and 3B.

A peripheral region 1016 to a side of the 1T1R cells 1002 accommodates peripheral devices 1018 (only one of which is shown). The peripheral devices 1018 may, for example, be metal-oxide-semiconductor field-effect transistors (MOSFETs), fin field-effect transistors (finFETs), gate-all-around field-effect transistors (GAA FETs), or some other suitable type of semiconductor device. Each of the peripheral devices 1018 comprises a pair of source/drain regions 1020 in the substrate 1008, as well as a gate electrode 1022 and a gate dielectric layer 1024 stacked between the source/drain regions 1020.

With reference to FIG. 10B, a cross-sectional view 1000b of some embodiments of the IC chip of FIG. 10A is provided along an axis orthogonal to that which the cross-sectional view 1000a of FIG. 10A is taken. The 1T1R cells 1002 comprise individual memory cells 102, individual drain-side conductive paths 1006, individual access transistors 114, and individual source-side conductive paths 1026. The memory cells 102 are each as their counterpart is described with regard to FIG. 1.

The access transistors 114 are on the substrate 1008, between the substrate 1008 and the interconnect structure 402, and are electrically separated by the trench isolation structure 1010. The access transistors 114 comprise individual drain regions 1004, individual source regions 1028, individual gate dielectric layers 1030, and individual gate electrodes 1032. The gate electrodes 1032 respectively overlie the gate dielectric layers 1030 and, in some embodiments, form word lines. The drain and source regions 1004, 1028 are doped regions of the substrate 1008 and each has an opposite doping type as an adjoining region of the substrate 1008. Further, the drain and source regions 1004, 1028 respectively border the gate electrodes 1032. The access transistors 114 may, for example, be MOSFETs, finFETs, GAA FETs, or some other suitable type of semiconductor device.

The drain-side conductive paths 1006 electrically couple the drain regions 1004 to the memory cells 102, and the source-side conductive paths 1026 electrically couple the source regions 1028 to source lines SL. The drain-side and source-side conductive paths 1006, 1026 are formed by the plurality of wires 404 and the plurality of vias 406. In some embodiments, the source lines SL and the bit lines BL electrically couple the memory cells 102 to the bias circuitry 112 and the control circuitry 116. In further embodiments, the gate electrodes 1032 are also coupled to the bias circuitry 112.

While FIGS. 10A and 10B are illustrated using memory-cell embodiments as in FIG. 1, memory-cell embodiments as in any of FIGS. 1, 2A-2B, 4, 5, 6, 7, 8A, and 9A-9E are amenable in alternative embodiments. For example, as illustrated by the cross-sectional view 1100 of FIG. 11, the memory cells 102 of FIGS. 10A and 10B may alternatively be configured as in FIG. 8A.

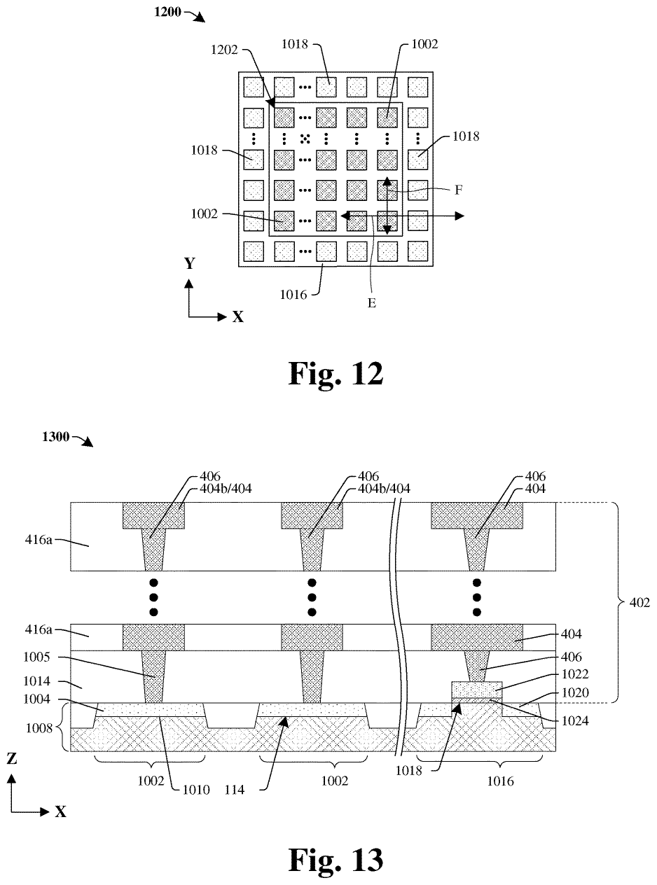

With reference to FIG. 12, a top layout view 1200 of some embodiments of the IC chip of FIGS. 10A and 10B is provided. The cross-sectional views 1000a, 1000b of FIGS. 10A and 10B may, for example, respectively be taken along lines E and F. The IC chip comprises a plurality of 1T1R cells 1002 in a plurality of rows and a plurality of columns, thereby forming a memory array 1202. Peripheral devices 1018 surround the memory array 1202 at a peripheral region 1016 of the IC chip. The peripheral devices 1018 may, for example, implement read/write circuitry and/or other suitable circuitry for operating the 1T1R cells 1002.

With reference to FIGS. 13-23, a series of cross-sectional views 1300-2300 of some embodiments of a method for forming an IC chip comprising memory cells 102 is provided, where the memory cells are integrated into individual 1T1R cells 1002 and comprise interfacial layers 104 consisting of semiconductor material. The cross-sectional views 1300-2300 may, for example, correspond to the IC chip of FIGS. 10A and 10B.

As illustrated by a cross-sectional view 1300 of FIG. 13, an interconnect structure 402 is partially formed over and electrically coupled to a plurality of access transistors 114 (only partially shown) and a peripheral device 1018. The access transistors 114 are individual to and respectively at a plurality of 1T1R cells 1002 being formed, and the peripheral device 1018 is at a peripheral region 1016 of the IC chip being formed. The access transistors 114 and the peripheral device 1018 are on and partially formed by a substrate 1008 and are separated by a trench isolation structure 1010 in the substrate 1008. The access transistors 114 and the peripheral device 1018 may, for example, be as described with regard to FIGS. 10A and 10B.

The interconnect structure 402 comprises a plurality of wires 404 and a plurality of vias 406 that are alternatingly stacked into wire levels and via levels in a dielectric structure. The dielectric structure comprises an ILD layer 1014 surrounding a plurality of contacts 1005 and a first IMD layer 416a over the ILD layer 1014. The plurality of wires 404 comprises a plurality of bottom electrode wires 404b along a top surface of the interconnect structure 402. The bottom electrode wires 404b are individual to and respectively at the 1T1R cells 1002 being formed. Further, the bottom electrode wires 404b are respectively electrically coupled to drain regions 1004 of the access transistors 114. The first IMD layer 416a may, for example, be formed by and/or using chemical vapor deposition (CVD), physical vapor deposition (PVD), atomic layer deposition (ALD), some other suitable deposition process(es), or any combination of the foregoing. The wires 404, the vias 406, and the contacts 1005 may, for example, be formed by and/or using CVD, PVD, ALD, electroless plating, electroplating, some other suitable deposition process(es), or any combination of the foregoing.

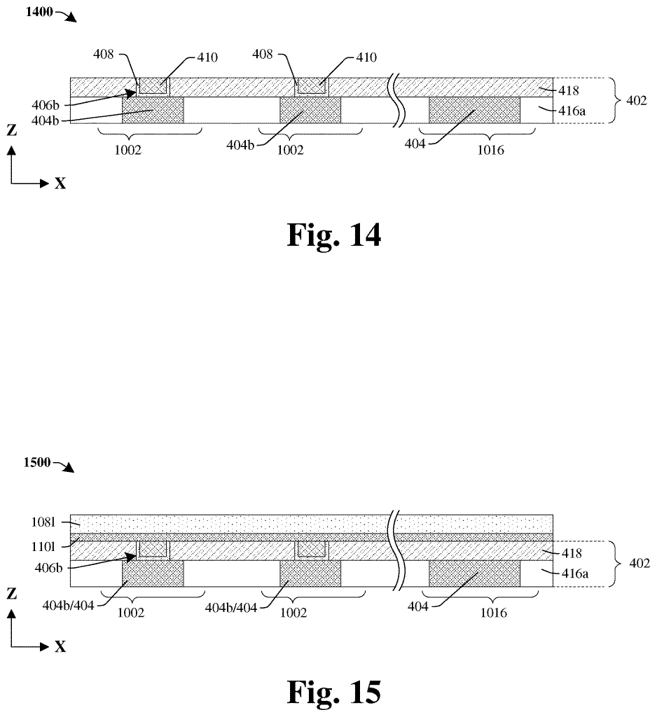

As illustrated by a cross-sectional view 1400 of FIG. 14, a first etch stop layer 418 is deposited or otherwise formed on the interconnect structure 402. Note that for drawing compactness, a lower portion of the interconnect structure 402 is omitted herein and in subsequent figures. The first etch stop layer 418 is a dielectric and may, for example, be deposited by CVD, PVD, ALD, some other suitable deposition process(es), or any combination of the foregoing.

Also illustrated by the cross-sectional view 1400 of FIG. 14, in some embodiments, BEVAs 406b are formed extending through the first etch stop layer 418 respectively to the bottom electrode wires 404b. The BEVAs 406b comprise individual BEVA bodies 410 and individual BEVA barriers 408 respectively cupping undersides of the BEVA bodies 410. The BEVA bodies 410 and/or the BEVA barriers 408 may, for example, be formed by and/or using CVD, PVD, ALD, some other suitable deposition process(es), or any combination of the foregoing. In some embodiments, BEVAs 406b are not formed, and instead gaps are etched into the etch stop layer, exposing the bottom electrode wires 404b.

As illustrated by a cross-sectional view 1500 of FIG. 15, a bottom electrode layer 110l is deposited over the BEVAs 406b and the first etch stop layer 418. The bottom electrode layer 110l may, for example, be deposited by CVD, PVD, ALD, some other suitable deposition process(es), or any combination of the foregoing. In embodiments without BEVAs 406b, the bottom electrode layer 110l is deposited directly onto the bottom electrode wires 404b.

Also illustrated by the cross-sectional view 1500 of FIG. 15, a ferroelectric layer 108l is deposited on the bottom electrode layer 110l. The deposition may, for example, be performed by CVD, PVD, ALD, the like, or any combination of the foregoing.

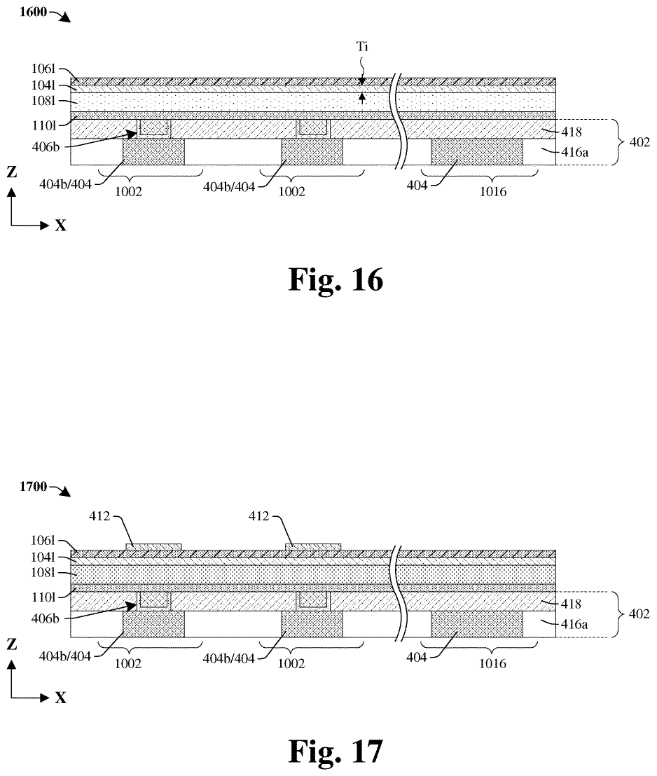

As illustrated by a cross-sectional view 1600 of FIG. 16, an interfacial layer 104l is deposited on the ferroelectric layer 108l, and a top electrode layer 106l is deposited on the interfacial layer 104l. The interfacial layer 104l may, for example, be deposited by CVD, PVD, ALD, some other suitable deposition process(es), or any combination of the foregoing. Similarly, the top electrode layer 106l may, for example, be deposited by CVD, PVD, ALD, some other suitable deposition process(es), or any combination of the foregoing.

In some embodiments, the interfacial layer 104l is or comprises elemental silicon, elemental germanium, gallium arsenide, silicon carbide, tin selenide, cadmium telluride, indium phosphide, boron arsenide, some other suitable semiconductors, or any combination of the foregoing. The interfacial layer 104l may has a band gap of less than or equal to 3 eV. For example, the interfacial layer 104l may be or comprise elemental germanium, with a band gap of 0.8 eV.

In some embodiments, the interfacial layer 104l has an amorphous structure so as to lower the dielectric constant. Alternatively, in some embodiments, the interfacial layer 104l has a crystalline structure so as to increase the dielectric constant. By altering the dielectric constant, the I/V readings of the memory cell 102 (see FIG. 3) during read operations are altered.

As illustrated by a cross-sectional view 1700 of FIG. 17, hard masks 412 individual to the 1T1R cells 1002 being formed are formed. As seen hereafter, the hard masks 412 have patterns for memory cells 102 being formed. A process for forming the hard masks 412 may, for example, comprise depositing a hard mask layer over the top electrode layer 106l and subsequently patterning the hard mask layer into the hard masks 412. The depositing may, for example, be performed by CVD, PVD, ALD, some other suitable deposition process(es), or any combination of the foregoing. The patterning may, for example, be performed by a photolithography/etching process or some other suitable patterning process.

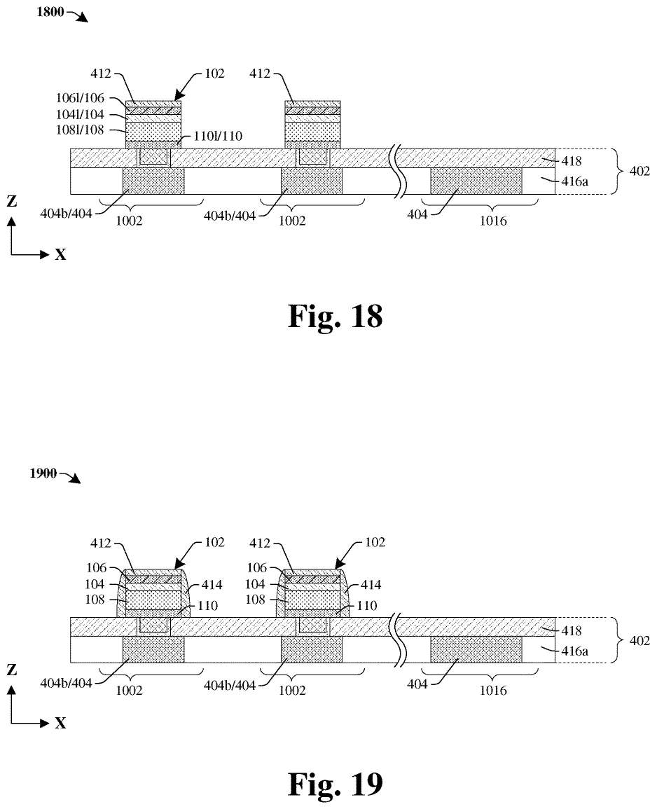

As illustrated by a cross-sectional view 1800 of FIG. 18, a etch is performed into the top electrode layer 106l, the interfacial layer 104l, the ferroelectric layer 108l, and the bottom electrode layer 110l with the hard masks 412 in place. In some embodiments in which the hard masks 412 are formed by a photolithography/etching process, an etch of the photolithography/etching process is the same as the etch into the top electrode layer 106l and others. The etch stops on the first etch stop layer 418, whereby the first etch stop layer 418 serves as an etch stop for the etch. Further, the etch transfers patterns of the hard masks 412 to the top electrode layer 106l, the interfacial layer 104l, the ferroelectric layer 108l, and the bottom electrode layer 110l, thereby forming memory cells 102 respectively overlying and on the BEVAs 406b. Individual segments of the top electrode layer 106l at the memory cells 102 are hereafter referred to as top electrodes 106, and individual segments of the bottom electrode layer 110l at the memory cells 102 are hereafter referred to as bottom electrodes 110. In some embodiments, the patterning of the interfacial layer 104l and the ferroelectric layer 108l delineates segments of the interfacial layers 104 and ferroelectric layers 108 individual to the memory cells 102, wherein the bottom electrode 110, the top electrode 106, and the segments of the interfacial layers 104 and ferroelectric layers 108 directly between the bottom electrode 110 and the top electrode 106 form a memory cell 102 of the memory cells.

In some embodiments, an etch back is performed into the top electrode layer, the interfacial layer, and the ferroelectric layer to remove horizontally extending segments of the top electrode layer, the interfacial layer, and the ferroelectric layer and to form a sidewall structure surrounding portions of the bottom electrode, wherein the sidewall structure comprises the top electrode and the segments of the interfacial layer and ferroelectric layer.

As illustrated by a cross-sectional view 1900 of FIG. 19, a sidewall spacer structure 414 is formed on common sidewalls formed by the hard masks 412, the top electrodes 106, the interfacial layers 104, the ferroelectric layers 108, and the bottom electrodes 110. A process for forming the sidewall spacer structure 414 may, for example, comprise: 1) depositing a sidewall spacer layer on the memory cells 102; and 2) etching back the sidewall spacer layer. Other suitable processes are, however, amenable. The sidewall spacer layer may, for example, be deposited by CVD, PVD, ALD, some other suitable deposition process(es), or any combination of the foregoing.

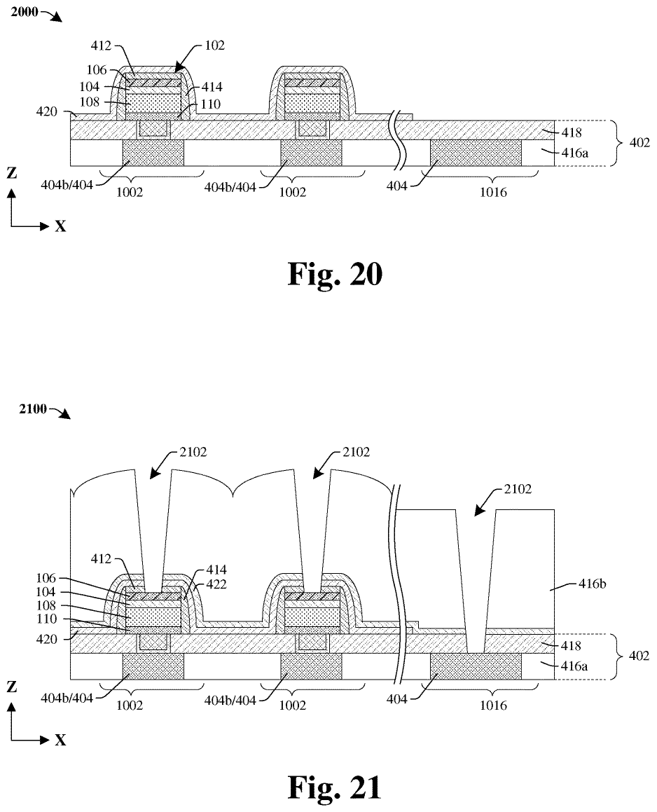

As illustrated by cross-sectional views 2000-2300 of FIGS. 20-23, the interconnect structure 402 is completed over and around the memory cells 102.

As illustrated by the cross-sectional view 2000 of FIG. 20, a second etch stop layer 420 is formed covering the memory cells 102 and laterally offset from the peripheral region 1016. A process for forming the second etch stop layer 420 as such may, for example, comprise: 1) depositing the second etch stop layer 420 covering the memory cells 102 and the peripheral region 1016; and 2) patterning the second etch stop layer 420 to remove it from the peripheral region 1016. Other suitable processes are, however, amenable. The second etch stop layer 420 may, for example, be deposited by CVD, PVD, ALD, some other suitable deposition process(es), or any combination of the foregoing. The patterning may, for example, be performed by a photolithography/etching process or some other suitable process.

As illustrated by the cross-sectional view 2100 of FIG. 21, a buffer layer 422 and a second IMD layer 416b are deposited covering the memory cells 102 and the peripheral region 1016 over the first and second etch stop layers 418, 420. In alternative embodiments, the buffer layer 422 is omitted. The buffer layer 422 and/or the second IMD layer 416b may, for example, be deposited by CVD, PVD, ALD, some other suitable deposition process(es), or any combination of the foregoing.

Also illustrated by the cross-sectional view 2100 of FIG. 21, the second IMD layer 416b, the buffer layer 422, and the first and second etch stop layers 418, 420 are patterned to form a plurality of via opening 2102. The via openings 2102 respectively expose the top electrodes 106 at the memory cells 102 and a wire 404 at the peripheral region 1016. The patterning may, for example, be performed by one or more photolithography/etching process(es) and/or some other suitable patterning process(es). In some embodiments, the first and second etch stop layers 418, 420 serve as etch stops while performing the etching of the photolithography/etching process(es).

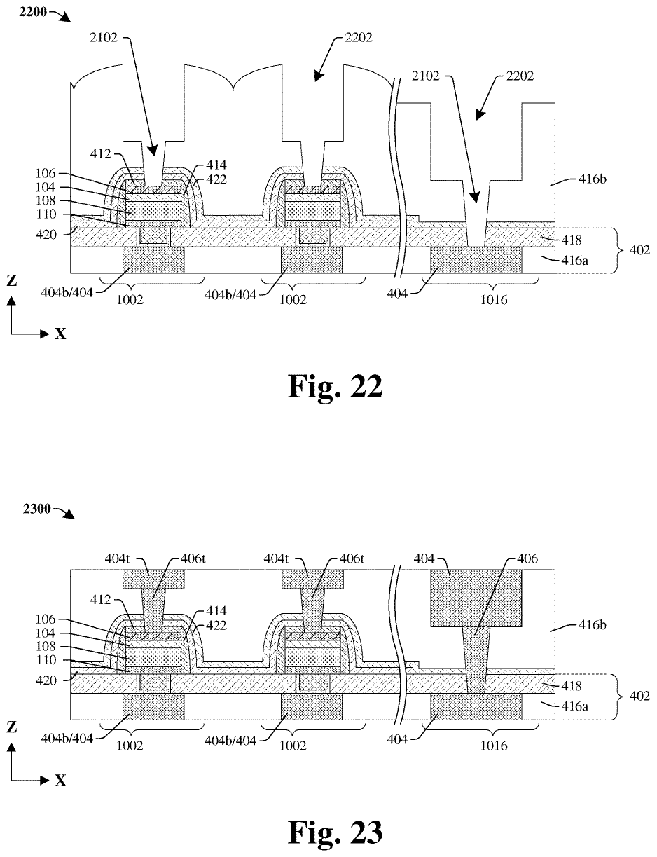

As illustrated by the cross-sectional view 2200 of FIG. 22, the second IMD layer 416b is further patterned to form a plurality of wire opening 2202 overlapping with the via openings 2102. The patterning may, for example, be performed by a photolithography/etching process and/or some other suitable patterning process(es).

As illustrated by the cross-sectional view 2300 of FIG. 23, a plurality of additional wires 404 and a plurality of additional vias 406 are formed filling the via openings 2102 (see, e.g., FIG. 21) and the wire openings 2202 (see, e.g., FIG. 22). The plurality of additional wires 404 respectively fill the wire openings 2202 and comprise a plurality of top electrode wires 404t individual to and respectively overlying the memory cells 102. The plurality of additional vias 406 respectively fill the via openings 2102 and comprise a plurality of TEVAs 406t individual to and respectively at the top electrodes 106. Further, the TEVAs 406t extend respectively from the top electrode wires 404t respectively to the top electrodes 106.

A process for forming the additional wires 404 and the additional vias 406 may, for example, comprise: 1) depositing a metal layer filling the via openings 2102 and the wire openings 2202; and 2) performing a planarization into the metal layer and the second IMD layer 416b until top surfaces of the second IMD layer 416b and the metal layer are level with each other. Other suitable processes are, however, amenable. The metal layer may, for example, be deposited by CVD, PVD, ALD, electroless plating, electroplating, some other suitable deposition process(es), or any combination of the foregoing.

While FIGS. 13-23 are described with reference to a method, it will be appreciated that the structures shown in FIGS. 13-23 are not limited to the method but rather may stand alone separate of the method. While FIGS. 13-23 are described as a series of acts, it will be appreciated that the order of the acts may be altered in other embodiments. For example, instead of forming the interfacial layer 104l between the ferroelectric layer 108l and the top electrode layer 106l, the interfacial layer 104l may be formed between the bottom electrode layer 110l and the ferroelectric layer 108l.

While FIGS. 13-23 are illustrated and described as a specific set of acts, some acts that are illustrated and/or described may be omitted in other embodiments. Further, acts that are not illustrated and/or described may be included in other embodiments. For example, an anneal may be performed after the ferroelectric layer 108l is deposited, resulting in the ferroelectric layer 108l having a higher ratio of the orthorhombic phase to other phases, increasing the remanent polarization (2Pr) and the data retention of the memory cell 102.

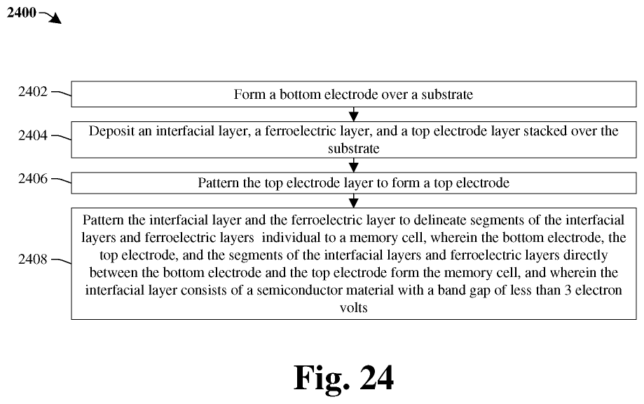

With reference to FIG. 24, a block diagram 2400 of some embodiments of the method of FIGS. 13-23 is provided. While the block diagram 2400 of FIG. 24 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

At 2402, a bottom electrode is formed over the substrate. See, for example, FIGS. 15 and 18.

At 2404, an interfacial layer, a ferroelectric layer, and a top electrode layer are deposited and stacked over the substrate. See, for example, FIGS. 15-16.

At 2406, the top electrode layer is patterned to form a top electrode. See, for example, FIG. 18.

At 2408, the interfacial layer and the ferroelectric layer are patterned to delineate segments of the interfacial layers and ferroelectric layers individual to a memory cell, wherein the bottom electrode, the top electrode, and the segments of the interfacial layers and ferroelectric layers directly between the bottom electrode and the top electrode form the memory cell, and wherein the interfacial layer consists of a semiconductor material with a band gap of less than 3 electron volts. See, for example, FIG. 18.

In some embodiments, the present disclosure provides an integrated chip including a first electrode made of a metal; a second electrode disposed over the first electrode; a ferroelectric layer between the first and second electrodes; and an interfacial layer separating the ferroelectric layer and the first electrode, the interfacial layer comprising a semiconductor material and configured to space the first electrode from the ferroelectric layer.

In some embodiments, the present disclosure provides an integrated circuit including a first electrode over a substrate; a ferroelectric layer disposed over the first electrode; a second electrode disposed over the ferroelectric layer; and an interfacial layer disposed over the first electrode and separating the first electrode and the ferroelectric layer, wherein there is no dielectric material directly between the first electrode and the second electrode.

In some embodiments, the present disclosure provides a method including: forming a bottom electrode over a substrate; depositing an interfacial layer, a ferroelectric layer, and a top electrode layer stacked over the substrate; patterning the top electrode layer to form a top electrode; and patterning the interfacial layer and the ferroelectric layer to delineate segments of the interfacial layers and ferroelectric layers individual to a memory cell, wherein the bottom electrode, the top electrode, and the segments of the interfacial layers and ferroelectric layers directly between the bottom electrode and the top electrode form the memory cell, and wherein the interfacial layer consists of a semiconductor material with a band gap of less than 3 electron volts.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a first electrode comprising a metal;
a second electrode disposed over the first electrode;
a ferroelectric layer between the first and second electrodes; and
an interfacial layer separating the ferroelectric layer and the second electrode, the interfacial layer comprising a semiconductor material and configured to space the second electrode from the ferroelectric layer.

2. The integrated chip of claim 1, further comprising bias circuitry, wherein the first electrode, the second electrode, the ferroelectric layer, and the interfacial layer are configured to function as a ferroelectric tunnel junction, and wherein the bias circuitry is configured to supply a tunneling current density greater than or equal to 100 A/cm² across the ferroelectric tunnel junction.

3. The integrated chip of claim 1, further comprising an intermediate layer with a first surface facing the interfacial layer and a second surface facing the ferroelectric layer and comprising a material of the ferroelectric layer and a material of the interfacial layer, and wherein a ratio of the material of the ferroelectric layer to the material of the interfacial layer monotonically increases from the first surface to the second surface.

4. The integrated chip of claim 1, wherein the interfacial layer has a first thickness greater than or equal to 50 angstroms and less than or equal to 1200 angstroms, and wherein the ferroelectric layer has a second thickness greater than or equal to 50 angstroms and less than or equal to 400 angstroms.

5. The integrated chip of claim 4, wherein the first thickness and the second thickness are in a ratio from a 1-to-1 ratio to a 3-to-1 ratio.

6. The integrated chip of claim 1, wherein the semiconductor material is amorphous silicon.

7. The integrated chip of claim 1, wherein the interfacial layer has a band gap of less than 3 electron volts.

8. An integrated circuit comprising:
a first electrode over a substrate;
a ferroelectric layer disposed over the first electrode;
a second electrode disposed over the ferroelectric layer; and
an interfacial layer disposed over the first electrode and separating the first electrode and the ferroelectric layer, wherein there is no dielectric material directly between the first electrode and the second electrode.

9. The integrated circuit of claim 8, wherein the ferroelectric layer has a first outer sidewall, the interfacial layer has a second outer sidewall, and one of the first electrode or the second electrode has a third outer sidewall aligned with the first outer sidewall and the second outer sidewall.

10. The integrated circuit of claim 8, wherein the second electrode is directly between outer sidewalls and directly above upper surfaces of the ferroelectric layer, the interfacial layer, and the first electrode.

11. The integrated circuit of claim 8, wherein the second electrode extends in a closed path around the first electrode, and wherein the first electrode has outer sidewalls that extend to an elevation level with an uppermost point of the second electrode.

12. The integrated circuit of claim 8, further comprising bias circuitry coupled to the first electrode and the second electrode and configured to supply a tunneling current with a tunneling current density equal to or greater than 100 A/cm² passing through the interfacial layer.

13. The integrated circuit of claim 8, wherein a bottom surface of the second electrode extends beneath a top surface of the first electrode.

14. A method of forming an integrated chip, comprising:
forming a bottom electrode over a substrate;
depositing an interfacial layer, a ferroelectric layer, and a top electrode layer stacked over the substrate;
patterning the top electrode layer to form a top electrode; and
patterning the interfacial layer and the ferroelectric layer to delineate segments of the interfacial layers and ferroelectric layers individual to a memory cell, wherein the bottom electrode, the top electrode, and the segments of the interfacial layer and the ferroelectric layer directly between the bottom electrode and the top electrode form the memory cell, and wherein the interfacial layer consists of a semiconductor material with a band gap of less than 3 electron volts.

15. The method of claim 14, further comprising:
forming a semiconductor device overlying and partially defined by the substrate before forming the bottom electrode; and
forming an interconnect structure comprising a plurality of wires and a plurality of vias alternatingly stacked into wire levels and via levels, wherein the interconnect structure electrically couples the semiconductor device to the memory cell.

16. The method of claim 14, wherein the patterning of the top electrode layer, the interfacial layer, and the ferroelectric layer comprises:
performing an etch back into the top electrode layer, the interfacial layer, and the ferroelectric layer to remove horizontally extending segments of the top electrode layer, the interfacial layer, and the ferroelectric layer and to form a sidewall structure surrounding portions of the bottom electrode, wherein the sidewall structure comprises the top electrode and the segments of the interfacial layer and the ferroelectric layer.

17. The method of claim 14, further comprising annealing the integrated chip after the top electrode layer is deposited, resulting in an intermediate layer forming between the interfacial layer and the ferroelectric layer, the intermediate layer extending from a first surface facing the interfacial layer where a same material as the interfacial layer has a mole percent of 99% to a second surface facing the ferroelectric layer where a same material as the ferroelectric layer has a mole percent of 99%.

18. The method of claim 14, further comprising:
depositing a bottom electrode layer before depositing the interfacial layer, the ferroelectric layer, and the top electrode layer; and
patterning the bottom electrode layer to form the bottom electrode after the patterning of the interfacial layer, the ferroelectric layer, and the top electrode layer.

19. The method of claim 18, wherein the patterning of the bottom electrode layer, the interfacial layer, and the ferroelectric layer further comprises:
forming a first mask on top of the top electrode layer; and
etching the bottom electrode layer, the ferroelectric layer, and the interfacial layer with the first mask in place to perform the patterning of the bottom electrode layer, the ferroelectric layer, and the interfacial layer.

20. The method of claim 14, further comprising depositing a bottom electrode layer before depositing the interfacial layer, the ferroelectric layer, and the top electrode layer, wherein the interfacial layer, the ferroelectric layer, and the top electrode layer are deposited directly between inner sidewalls of the bottom electrode layer.
